(19) United States
(12) Patent Application Publication
(10) Pub. No.: US 2026/0123529 A1
(43) Pub. Date: Apr. 30, 2026

(54) INTEGRATED FAN-OUT PACKAGE AND MANUFACTURING METHOD THEREOF

(71) Applicant: Taiwan Semiconductor Manufacturing Company, Ltd., Hsinchu (TW)

(72) Inventors: Chung-Ming Weng, Taichung City (TW); An-Jhih Su, Taoyuan City (TW); Yen-Liang Lin, Taichung City (TW); Tzuan-Horng Liu, Taoyuan City (TW); Jo-Mei Wang, New Taipei City (TW)

(73) Assignee: Taiwan Semiconductor Manufacturing Company, Ltd., Hsinchu (TW)

(21) Appl. No.: 18/931,076

(22) Filed: Oct. 30, 2024

(51) Int. Cl. H01L 23/00; H01L 23/31; H01L 25/065; H01L 25/16

(52) U.S. Cl. CPC H10W 90/00; H10W 70/09; H10W 70/60; H10W 70/6528; H10W 74/111; H10W 90/10

(57) ABSTRACT

An integrated fan-out package includes a redistribution structure, a die, an encapsulant and a conductive bump. The redistribution structure has a first surface and a second surface opposite to the first surface, wherein the redistribution structure comprises an under-bump metallization (UBM) pattern disposed on the first surface. The die is disposed on the second surface of the redistribution structure. The encapsulant encapsulates the die. The conductive bump is disposed on the UBM pattern, wherein the UBM pattern has a configuration surface over the first surface, the conductive bump is located on the configuration surface, and a bottom area of the conductive bump is smaller than an area of configuration surface.

### BACKGROUND

The semiconductor industry has experienced rapid growth due to continuous improvements in the integration density of various electronic components (i.e., transistors, diodes, resistors, capacitors, etc.). For the most part, the improvement in integration density has come from repeated reductions in minimum feature size, which allows more of the smaller components to be integrated into a given area. These smaller electronic components also require smaller packages that utilize less area than previous packages. Currently, integrated fan-out packages are becoming increasingly popular for their compactness. However, there are many challenges related to integrated fan-out packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F are schematic cross-sectional views illustrating a manufacturing process of an integrated fan-out package in accordance with some embodiments of the disclosure.

FIG. 2 is a schematic cross-sectional view illustrating an integrated fan-out package in accordance with some alternative embodiments of the disclosure.

FIG. 3 is a schematic cross-sectional view illustrating an integrated fan-out package in accordance with some alternative embodiments of the disclosure.

FIG. 4 is a schematic cross-sectional view illustrating an integrated fan-out package in accordance with some alternative embodiments of the disclosure.

FIG. 5 is a schematic cross-sectional view illustrating an integrated fan-out package in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

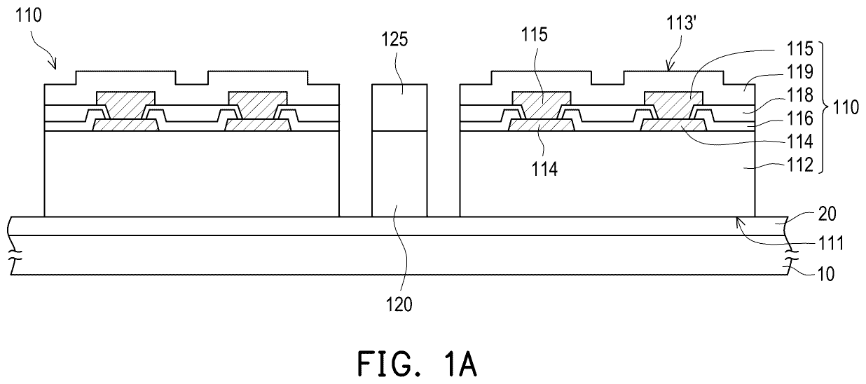

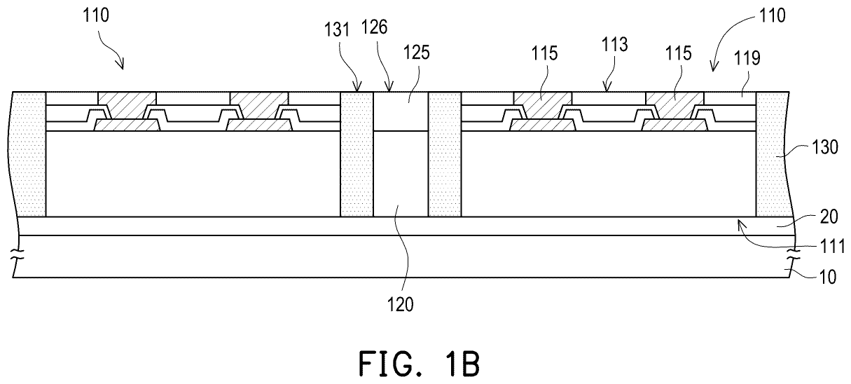

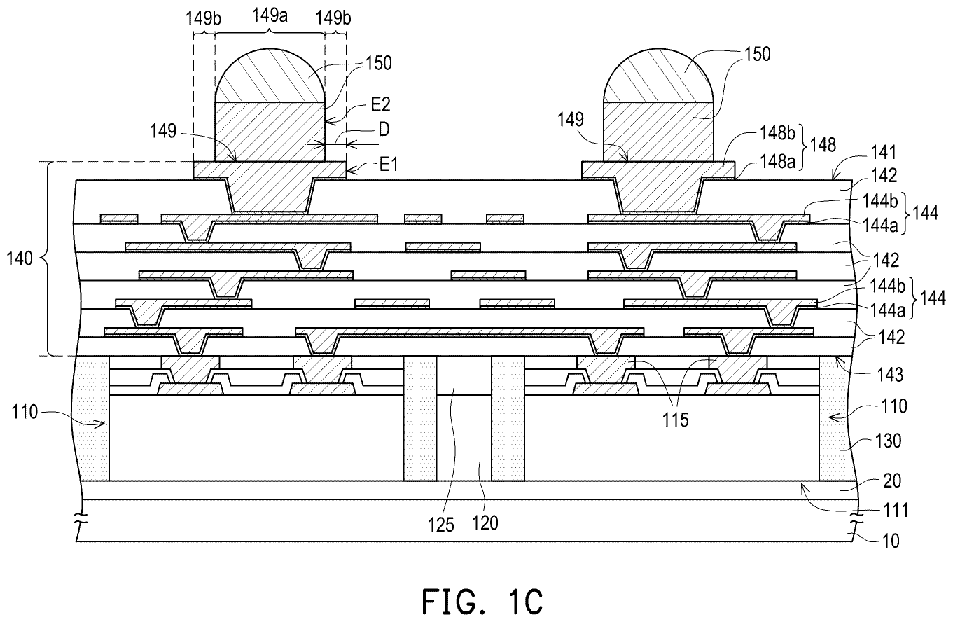

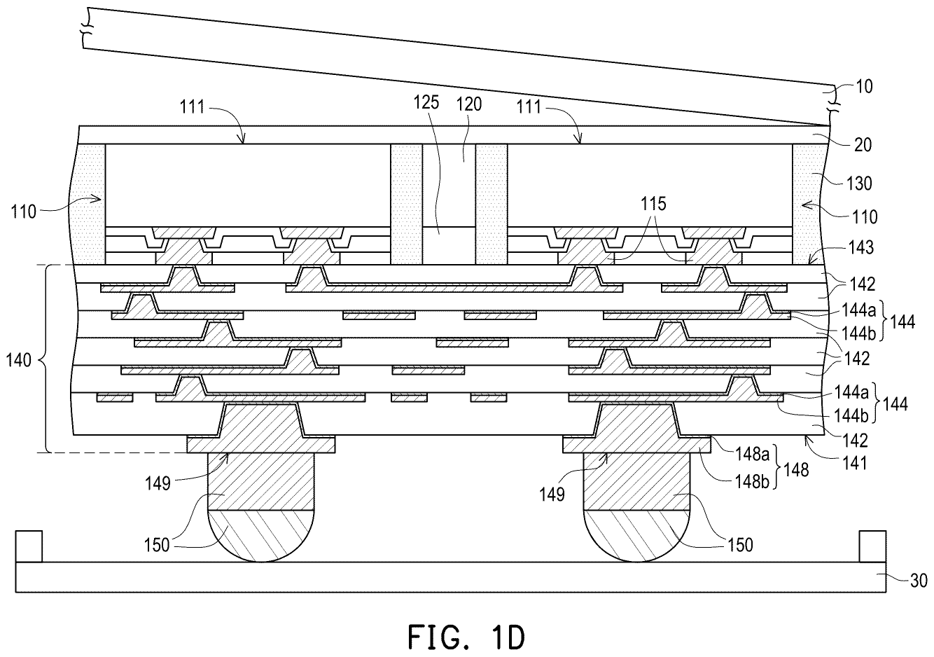

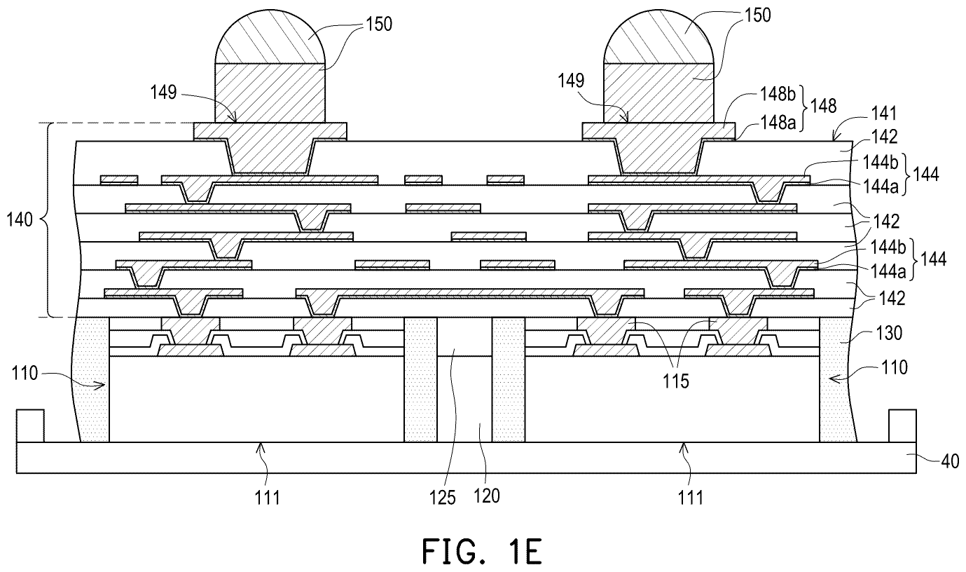

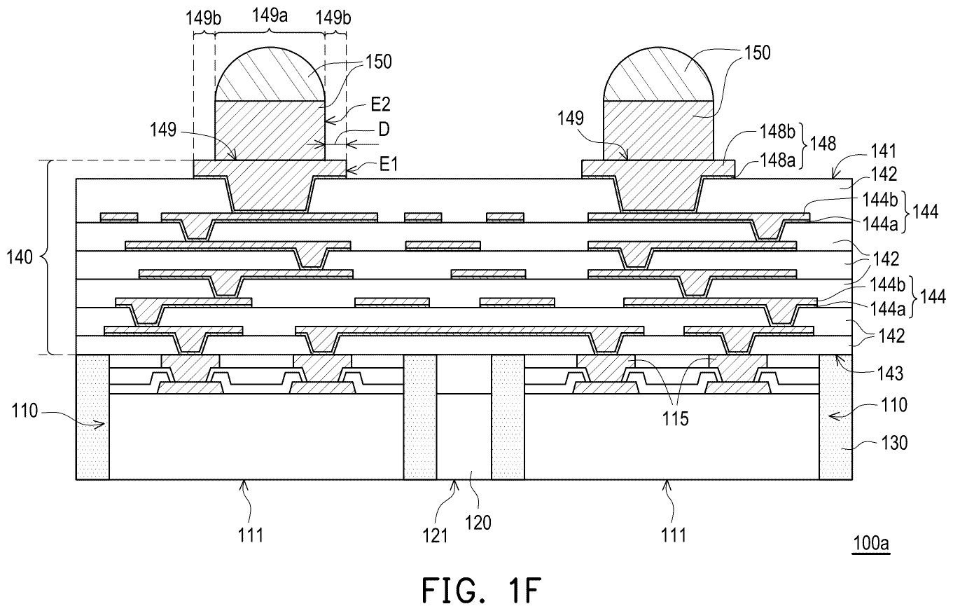

FIG. 1A to FIG. 1F are schematic cross-sectional views illustrating a manufacturing process of an integrated fan-out package in accordance with some embodiments of the disclosure. Referring to FIG. 1A, a carrier 10 is provided, and a release layer 20 is formed on the carrier 10. The carrier 10 may be a glass carrier substrate, a ceramic carrier substrate, or the like. The release layer 20 may be formed from a polymer-based material that may be removed together with the carrier 10 from the overlying structure to be formed in a subsequent step. In some embodiments, the release layer 20 is an epoxy-based heat release material that loses its adhesive properties when heated, such as a light-to-heat-conversion (LTHC) release coating. In other embodiments, the release layer 20 is an UV glue that loses its adhesive properties when exposed to ultra-violet (UV) light. The release layer 20 may be dispensed in liquid form and be cured. The release layer 20 may be a laminate film laminated to the carrier 10, or the like. The top surface of the release layer 20 may be flattened and may have a high degree of flatness.

Referring to FIG. 1A again, at least one die (two dies 110 are schematically shown) is placed on the carrier 10 through a pick-and-place process. The dies 110 are placed on the carrier 10 separately from each other. In some embodiments, each of the dies 110 includes a semiconductor substate 112, a plurality of conductive pads 114, a plurality of metallic posts 115, a passivation layer 116, a post-passivation layer 118 and a protection layer 119. In some embodiments, the conductive pads 114 are disposed over the semiconductor substrate 112. The passivation layer 116 is formed over the semiconductor substrate 112 and has contact openings that partially expose the conductive pads 114. The semiconductor substrate 112 may be a silicon substrate including active components (e.g., transistors or the like) and passive components (e.g., resistors, capacitors, inductors, or the like) formed therein. The conductive pads 114 may be aluminum pads, copper pads, or other suitable metal pads. The passivation layer 116 may be a silicon oxide layer, a silicon nitride layer, a silicon oxy-nitride layer, or a dielectric layer formed by other suitable dielectric materials. Furthermore, the post-passivation layer 118 is formed over the passivation layer 116. The post-passivation layer 118 covers the passivation layer 116 and has a plurality of contact openings. The conductive pads 114 are partially exposed by the contact openings of the post-passivation layer 118. The post-passivation layer 118 may be a polyimide layer, a PBO layer, or a dielectric layer formed by other suitable polymers. In addition, the metallic posts 115 are formed on the conductive pads 114. In some embodiments, the metallic posts 115 are plated on the conductive pads 114. The protection layer 119 is formed on the post-passivation layer 118 to cover the metallic posts 115. As illustrated in FIG. 1A, each of the dies 110 respectively has a rear surface 111 and a front surface 113′ opposite to the rear surface 111. In some embodiments, the rear surface 111 of each of the dies 110 is adhered to the carrier 10 through the release layer 20. On the other hand, the front surface 113′ of each of the dies 110 faces upward and is exposed.

In some embodiments, a dummy die 120 is placed on the carrier 10 through a pick-and-place process, where the dummy die 120 is located between the two dies 110, and the dummy die 120 is electrically floating. Herein, when elements are described as “dummy”, the elements are electrically floating or electrically isolated from other elements. For example, the dummy die 120 does not include functional circuits, devices or metallization structures therein. That is, the dummy die 120 is not electrically connected to other conductive elements in the subsequently formed integrated fan-out package 100a (shown in FIG. 1F) and do not contribute to signal transmission during the operation of the subsequently formed integrated fan-out package 100a. In some embodiments, the dummy die 120 has a support function to maintain the stress balance. In some embodiments, a protection layer 125 is formed on the dummy die 120 to cover the dummy die 120. In some embodiments, the protection layer 125 made of the same material as the protection layer 119.

In some embodiments, the dies 110 are logic dies (e.g., central processing unit (CPU), graphics processing unit (GPU), system-on-a-chip (SoC), application processor (AP), microcontroller, etc.), memory dies (e.g., dynamic random access memory (DRAM) die, static random access memory (SRAM) die, etc.), power management dies (e.g., power management integrated circuit (PMIC) die), radio frequency (RF) dise, sensor dies, micro-electro-mechanical-system (MEMS) dies, signal processing dies (e.g., digital signal processing (DSP) die), front-end dies (e.g., analog front-end (AFE) dies), the like, or combinations thereof. In some embodiments, the dies 110 are stacked devices that each includes multiple semiconductor substrates 112. For example, the dies 110 are a memory devices such as hybrid memory cube (HMC) modules, high bandwidth memory (HBM) modules, or the like that include multiple memory dies. In some other embodiments, the dies 110 include multiple semiconductor substrates 112 interconnected by through-substrate vias (TSVs). Each of the semiconductor substrates 112 may (or may not) have an interconnect structure.

Referring to FIG. 1A and FIG. 1B, an encapsulation material is formed on the release layer 20 to encapsulate the dies 110 and the dummy die 120. In some embodiments, the encapsulation material includes a molding compound, a molding underfill, a resin (such as epoxy), or the like. The encapsulation material may be formed by a molding process, such as a compression molding process. Furthermore, the encapsulation material, the protection layer 125 and the protection layer 119 of the dies 110 are partially removed until top surfaces of the metallic posts 115 are exposed. After the encapsulation material is partially removed, an encapsulant 130 is formed to laterally encapsulate the dies 110, the dummy die 120 and the protection layer 125. In some embodiments, the encapsulant material is partially removed by a mechanical grinding process and/or a chemical mechanical polishing (CMP) process. In some embodiments, during the grinding process of the encapsulant material, the protection layer 119 is partially removed to reveal the metallic posts 115. In some embodiments, portions of the metallic posts 115 are slightly removed as well. After performing the removal process of the encapsulation material, the protection layer 125 and the protection layer 119, each of the dies 110 has an active surface 113 and the rear surface 111 opposite to the active surface 113. The exposed portion of the metallic posts 115 is revealed on the active surface 113 of each of the dies 110. In some embodiments, the encapsulant 130 encapsulates the sidewalls of the dies 110, the sidewalls of the dummy die 120 and the sidewalls of the protection layer 125. As shown in FIG. 1B, the top surface 131 of the encapsulant 130, the active surface 113 of each of the dies 110 and the top surface 126 of the protection layer 125 are substantially coplanar.

Referring to FIG. 1C, a redistribution structure 140 is formed on the encapsulant 130, the dies 110 and the protection layer 125. In some embodiments, the redistribution structure 140 has a first surface 141 and a second surface 143 opposite to the first surface 141 and includes a plurality of dielectric layers 142, a plurality of conductive patterns 144, and a plurality under-bump metallization (UBM) patterns 148. The dielectric layer 142 and the conductive patterns 144 are stacked alternately. In some embodiments, the conductive patterns 144 transmit signals vertically and transmit signals horizontally. The UBM patterns 148 are disposed on the first surface 141, and the dies 110 and the dummy die 120 are disposed on the second surface 143. In some embodiments, some of the conductive patterns 144 penetrate through the underlying dielectric layer 142 to render electrical connection between the conductive patterns 144 located at different level heights. In some embodiments, the bottommost conductive patterns 144 penetrate through the bottommost dielectric layer 142 to be in physical contact with the metallic posts 115 of the dies 110, so as to electrically connect the redistribution structure 140 with the dies 110. In some embodiments, the UBM pattern 148 is formed by a photolithography process.

Referring to FIG. 1C again, in some embodiments, the thickness of the dielectric layer 142 with the second surface 143 and the thickness of the middle dielectric layer 142 are between 1 micrometer and 50 micrometers, and the thickness of the dielectric layer 142 with the first surface 141 is between 1 micrometer and 50 micrometers, but not limited thereto. In some embodiments, the material of the dielectric layer 142 includes polyimide, epoxy resin, acrylic resin, phenol resin, benzocyclobutene (BCB), polybenzoxazole (PBO), or any other suitable polymer-based dielectric material. Alternatively, the dielectric layer 142 may be formed of oxides or nitrides, such as silicon oxide, silicon nitride, aluminum oxide, hafnium oxide, hafnium zirconium oxide, or the like. In some embodiments, the dielectric layer 142 includes resin mixed with filler. The dielectric layer 142 may be formed by suitable fabrication techniques, such as spin-on coating, chemical vapor deposition (CVD), plasma-enhanced chemical vapor deposition (PECVD), or the like.

In some embodiments, each of the conductive patterns 144 includes a seed layer 144a and a conductive layer 144b disposed on the seed layer 144a. In some embodiments, a material of the seed layer 144a is formed through a sputtering process, a physical vapor deposition (PVD) process, or the like. In some embodiments, the seed layer 144a is constituted by two sub-layers. The first sub-layer may include titanium, titanium nitride, tantalum, tantalum nitride, other suitable materials, or a combination thereof. On the other hand, the second sub-layer may include copper, copper alloys, or other suitable choice of materials. In some embodiments, a material of the conductive layer 144b includes copper, copper alloys, or the like. The conductive layer 144b is formed by electroplating, deposition, immersion plating, or the like. In some embodiments, the thickness of the conductive pattern 144 is, for example, 5 micrometers, but not limited thereto.

Similarly, each of the UBM patterns 148 includes a seed layer 148a and a conductive layer 148b disposed on the seed layer 148a. In some embodiments, a material of the seed layer 148a is formed through a sputtering process, a physical vapor deposition (PVD) process, or the like. In some embodiments, the seed layer 148a is constituted by two sub-layers. The first sub-layer may include titanium, titanium nitride, tantalum, tantalum nitride, other suitable materials, or a combination thereof. On the other hand, the second sub-layer may include copper, copper alloys, or other suitable choice of materials. In some embodiments, a material of the conductive layer 148b includes copper, copper alloys, or the like. The conductive layer 148b is formed by electroplating, deposition, immersion plating, or the like. In some embodiments, the thickness of the UBM pattern 148 is at least greater than 2 micrometers, for example, 8 micrometers, but not limited thereto.

Referring to FIG. 1C again, a plurality of conductive bumps 150 are respectively formed on the UBM patterns 148, wherein each of the UBM pattern 148 has a configuration surface 149 over the first surface 141, the conductive bump 150 is located on the configuration surface 149, and a bottom area of the conductive bump 150 is smaller than an area of configuration surface 149. Namely, the configuration surface 149 of the UBM pattern 148 is larger than the contact surface of the conductive bump 150 and the configuration surface 149. The conductive bump 150 may include a copper pillar. The conductive bump 150 may include controlled collapse of chip connection bump (C4 bump). The C4 bump can be formed by initially forming a tin layer by any suitable method (such as evaporation, plating, printing, solder transfer); and then performing a reflow to shape the material into the desired bump shape. In some embodiments, the above-mentioned C4 bump is lead-free solder C4 bump. In some other embodiments, the above-mentioned C4 bump includes copper pillar and lead-free solder cap covering the copper pillar. In some embodiments, the above-mentioned C4 bump comprises a material such as tin, or other suitable materials, such as silver or copper. In an embodiment in which the C4 bump is a tin solder bump, the C4 bump may be formed by initially forming a layer of tin through any suitable method such as evaporation, electroplating, printing, solder transfer, ball placement, or the like. Once a layer of tin has been formed on the structure, a reflow is performed in order to shape the material into the bump shape with a diameter, e.g., of about 80 m. The conductive bumps 150 may land on and be in contact with the conductive layer 148b of the UBM patterns 148, wherein the conductive bumps 150 are electrically connected to the UBM patterns 148.

On the other hand, referring to FIG. 1C again, the configuration surface 149 has a first area 149a and a second area 149b surrounding the first area 149a. In some embodiments, when view from above, the configuration surface 149 is a circular-shaped region, and the shape of the second area 149b is annular region surrounding the above-mentioned circular-shaped region. The conductive bump 150 is located in the first area 149a, and a first edge E1 of the second area 149b protrudes a distance D relative to a second edge E2 of the conductive bump 150. Namely, the size of the UBM pattern 148 is larger than the size of the conductive bump 150. In some embodiments, the distance D is between 0.5 micrometers and 50 micrometers. In some embodiments, a ratio of the distance D to the width of the bottom surface of the conductive bump 150 is between 0.01 and 0.5.

Referring to FIG. 1C and FIG. 1D, before performing the de-bonding process, a frame mount process is performed to mount the resulted structure on a frame 30. The structure illustrated in FIG. 1C is flipped upside down and is placed on the frame 30, and the conductive bump 150 is in direct contact with the frame 30. And then, the carrier 10 and the release layer 20 are removed to expose the rear surfaces 111 of the dies 110. In some embodiments where the release layer 20 (e.g., the LTHC film) is formed on the carrier 10, the carrier 10 is de-bonded by exposing to a laser or UV light. The laser or UV light breaks the chemical bonds of the release layer 20 that binds to the carrier 10, and the carrier 10 may then be de-bonded. Residues of the release layer 20, if any, may be removed by a cleaning process performed after the carrier de-bonding process.

Referring to FIG. 1D and FIG. 1E, the structure illustrated in FIG. 1D is flipped upside down and is placed on a dicing tape 10, and the rear surfaces 111 of the dies 110 is in direct contact with the dicing tap 10. Thereafter, the frame 30 is removed to expose the conductive bump 150. In some embodiments, a singulation process may be performed to singulate the resulted structure illustrated in FIG. 1E after removing the frame 30. In some embodiments, the singulation process typically involves dicing with a rotation blade and/or a laser beam. In other words, the singulation process includes a laser cutting process, a mechanical cutting process, a laser grooving process, other suitable processes, or a combination thereof. For example, a laser grooving process may be performed on the unsingulated structure to form trenches (not shown) in the said structure. Thereafter, a mechanical cutting process may be performed on the locations of the trenches to cut through the said structure, so as to obtain an integrated fan-out package 100a shown in FIG. 1F. So far, the manufacturing of the integrated fan-out package 100a has been completed.

In terms of the structure, referring to FIG. 1F again, the integrated fan-out package 100a includes the redistribution structure 140, the dies 110, the encapsulant 130 and the conductive bump 150. The redistribution structure 140 has the first surface 141 and the second surface 143 opposite to the first surface 141, wherein the redistribution structure 140 includes the UBM pattern 148 disposed on the first surface 141. The dies 110 are disposed on the second surface 143 of the redistribution structure 140. The encapsulant 130 encapsulates the dies 110. The conductive bump 1150 is disposed on the UBM pattern 148, namely, the redistribution structure 140 is located between the dies 110 and the conductive bump 150. The UBM pattern 148 has the configuration surface 149 over the first surface 141, the conductive bump 150 is located on the configuration surface 149, and the area of configuration surface 149 is greater than and covers the orthographic projection area of the conductive bump 150 on the configuration surface 149. On the other hand, the configuration surface 149 has the first area 149a and the second area 149b surrounding the first area 149a. The conductive bump 150 is located in the first area 149a, and the first edge E1 of the second area 149b protrudes the distance D relative to the second edge E2 of the conductive bump 150. Namely, the configuration surface 149 of the UBM pattern 148 is larger than the contact surface of the conductive bump 150 and the configuration surface 149, in other words, the size of the UBM pattern 148 is larger than the size of the conductive bump 150.

In some embodiments, the conductive bump 150 includes the controlled collapse chip connection (C4) bump. In some embodiments, the integrated fan-out package 100a further includes the dummy die 120 disposed on the second surface 143 of the redistribution structure 140 and located between the dies 110, but not limited thereto. The encapsulant 130 further encapsulates the dummy die 120, and the encapsulant 130 exposes the rear surfaces 111 of the dies 110 and the rear surface 121 of the dummy die 120 to facilitate heat dissipation. In some embodiments, the peripheral surface of the encapsulant 130 is flush with the peripheral surface of the redistribution structure 140. In some implementations, the integrated fan-out package 100a may be applied in one or more facilities, such as an outsourced assembly and test (OSAT) facility, and/or a manufacturing facility, among other examples.

Since the size of the UBM pattern 148 of this embodiment is larger than the size of the conductive bump 150, it can be used as an interface barrier layer between the conductive bump 150 and the outmost dielectric layer 142 having the first surface 141, which can avoid cracks in the dielectric layer 142 adjacent to the conductive bump 150 from affection conductive patterns 144 when the integrated fan-out package 100a is bonded on the substrate in the following stages, and can effectively enhance the interface robustness of the integrated fan-out package 100a. In brief, the large-size UBM pattern 148 can disperse the stress when the integrated fan-out package 100a is bonded on the substrate, thereby effectively enhancing the interface strength. Therefore, the integrated fan-out package 100a of the present embodiment has batter structural reliability.

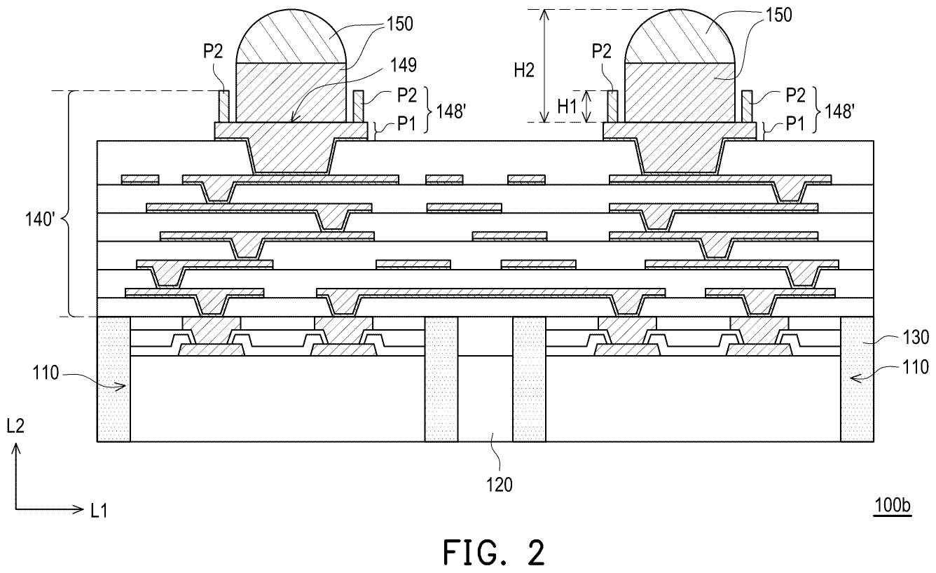

FIG. 2 is a schematic cross-sectional view illustrating an integrated fan-out package in accordance with some alternative embodiments of the disclosure. Referring to FIG. 2, the integrated fan-out package 100b in FIG. 2 is similar to the integrated fan-out package 100a in FIG. 1F, so similar elements are denoted by the same reference numeral and the detailed description thereof is omitted herein. The difference between the integrated fan-out package 100b in FIG. 2 and the integrated fan-out package 100a in FIG. 1F lies in that in the integrated fan-out package 100b, the UBM pattern 148′ of the redistribution structure 140′ includes a first portion P1 and a second portion P2. The first portion P1 has the configuration surface 149, and the second portion P2 is disposed on the configuration surface 149 and surrounds the conductive bump 150. The second portion P2 is in physical contact with the configuration surface 149 of the first portion P1.

In some embodiments, a first extending direction L1 of the first portion P1 is different from a second extending direction L2 of the second portion P2. In some embodiments, the first extending direction L1 is perpendicular to the second extending direction L2, but not limited thereto. In some embodiments, a first height H1 of the second portion P2 is smaller than a second height H2 of the conductive bump 150, but not limited thereto. In some embodiments, a ratio of the second height H2 to the first height H1 is between 5 and 60. In some embodiments, the first height H1 is between 2 micrometers and 30 micrometers. In some embodiments, the second height H2 is between 10 micrometers and 150 micrometers. In some embodiments, the peripheral surface of the first portion P1 is aligned with the peripheral surface of the second portion P2. In some embodiments, the peripheral surface of the first portion P1 protrudes a distance relative to the peripheral surface of the second portion P2. In some embodiments, the width of the second portion P2 is between 1 micrometer and 15 micrometers. In some embodiments, the second portion P2 is formed after forming the first portion P1. In some embodiments, the UBM pattern 148′ is formed by a photolithography process. Since the UBM pattern 148′ has the second portion P2, it can further enhance the blocking effect and make the integrated fan-out package 100b with better reliability.

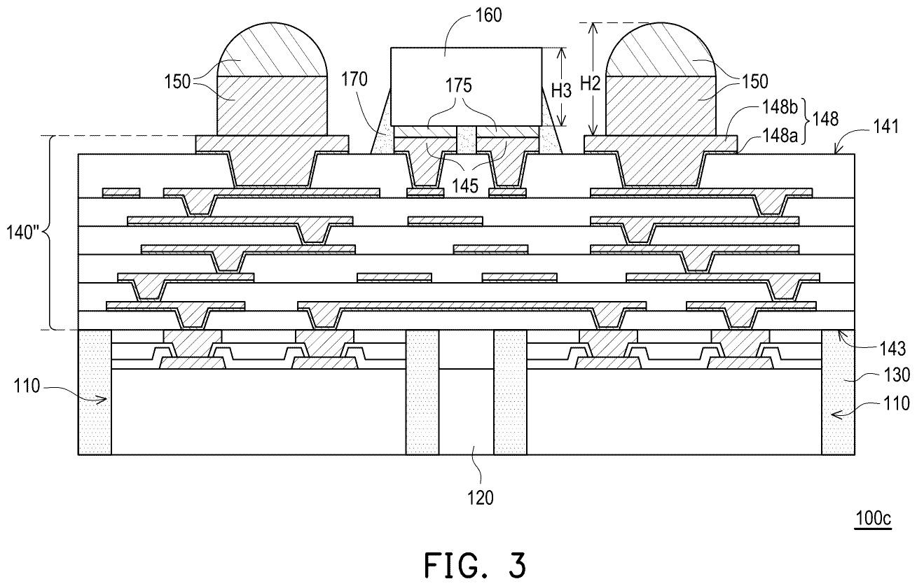

FIG. 3 is a schematic cross-sectional view illustrating an integrated fan-out package in accordance with some alternative embodiments of the disclosure. Referring to FIG. 3, the integrated fan-out package 100c in FIG. 3 is similar to the integrated fan-out package 100a in FIG. 1F, so similar elements are denoted by the same reference numeral and the detailed description thereof is omitted herein. The difference between the integrated fan-out package 100c in FIG. 3 and the integrated fan-out package 100a in FIG. 1F lies in that in the integrated fan-out package 100c further includes an integrated passive device (IPD) 160 disposed on the first surface 141 of the redistribution structure 140″. The IPD 160 may be mounted on these topmost pads 145 of the redistribution structure 140″ through the conductive joints 175, and the IPD 160 is electrically connected to the redistribution structure 140″ through the conductive joints 175. In some embodiments, the height H3 of the IPD 160 is smaller than the height H2 of the conductive bump 150, but not limited thereto. In some embodiments, the integrated fan-out package 100c further includes an underfill 170 disposed between the IPD 160 and the redistribution structure 140″ to cover the conductive joints 175 and the pads 145 of the redistribution structure 140″. In some embodiments, the IPD 160 includes passive devices such as resistors, inductors, capacitors, fuses, jumpers, combinations thereof, or the like. In some embodiments, the conductive joints 175 include solder joints, BGA joints, or the like. In some embodiments, the conductive joints 175 are made of a conductive material with low resistivity, such as Sn, Pb, Ag, Cu, Ni, Bi, or an alloy thereof. After the IPD 160 is mounted to some of the topmost pads 145, a reflow process is performed to securely fix the IPD 160 on these topmost pads 145. In some embodiments, the material of the underfill 170 is an insulating material and include a resin (e.g., epoxy resin), a filler material, a stress release agent (SRA), an adhesion promoter, other material, or a combination thereof. In some alternative embodiments, formation of the underfill 170 may be omitted.

In some embodiments, the IPD 160 is placed on the first surface 141 of the redistribution structure 140″ before forming the conductive bumps 150. In some embodiments, the IPD 160 is placed on the first surface 141 of the redistribution structure 140″ after forming the conductive bumps 150 and before performing the de-bonding process. In some embodiments, the UBM pattern 148 is made in the same process as the pads 145, but not limited thereto. Namely, the UBM pattern 148 can be made with the pads 145 for process integration. In some embodiments, a space between the UBM pattern 148 and the pad 145 is, for example, more than 1 micrometer.

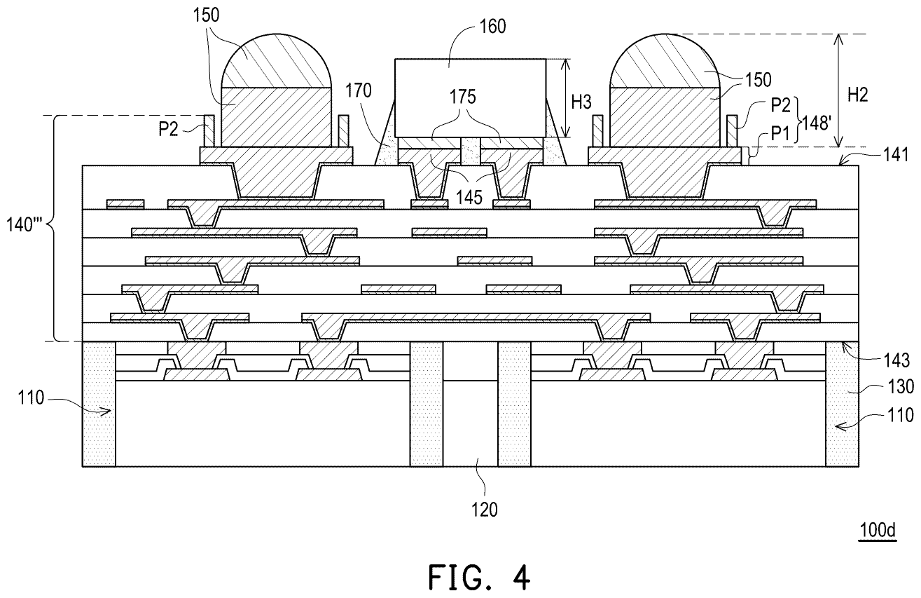

FIG. 4 is a schematic cross-sectional view illustrating an integrated fan-out package in accordance with some alternative embodiments of the disclosure. Referring to FIG. 4, the integrated fan-out package 100d in FIG. 4 is similar to the integrated fan-out package 100b in FIG. 2, so similar elements are denoted by the same reference numeral and the detailed description thereof is omitted herein. The difference between the integrated fan-out package 100d in FIG. 4 and the integrated fan-out package 100b in FIG. 2 lies in that in the integrated fan-out package 100d further includes an IPD 160 disposed on the first surface 141 of the redistribution structure 140′″. The IPD 160 may be mounted on these topmost pads 145 of the redistribution structure 140′″ through the conductive joints 175, and the IPD 160 is electrically connected to the redistribution structure 140′″ through the conductive joints 175. In some embodiments, the height H3 of the IPD 160 is smaller than the height H2 of the conductive bump 150, but not limited thereto. In some embodiments, the integrated fan-out package 100d further includes an underfill 170 disposed between the IPD 160 and the redistribution structure 140′″ to cover the conductive joints 175 and the pads 145 of the redistribution structure 140′″. In some embodiments, the IPD 160 includes passive devices such as resistors, inductors, capacitors, fuses, jumpers, combinations thereof, or the like. In some embodiments, the conductive joints 175 include solder joints, BGA joints, or the like. In some embodiments, the conductive joints 175 are made of a conductive material with low resistivity, such as Sn, Pb, Ag, Cu, Ni, Bi, or an alloy thereof. After the IPD 160 is mounted to some of the topmost pads 145, a reflow process is performed to securely fix the IPD 160 on these topmost pads 145. In some embodiments, the material of the underfill 170 is an insulating material and include a resin (e.g., epoxy resin), a filler material, a stress release agent (SRA), an adhesion promoter, other material, or a combination thereof. In some alternative embodiments, formation of the underfill 170 may be omitted.

In some embodiments, the IPD 160 is placed on the first surface 141 of the redistribution structure 140′″ before forming the conductive bumps 150. In some embodiments, the IPD 160 is placed on the first surface 141 of the redistribution structure 140′″ after forming the conductive bumps 150 and before performing the de-bonding process. In some embodiments, the UBM pattern 148 is produced in the same process as the pads 145, but not limited thereto. Namely, the UBM pattern 148 can be made with the pads 145 for process integration. In some embodiments, a space between the UBM pattern 148 and the pad 145 is, for example, more than 1 micrometer.

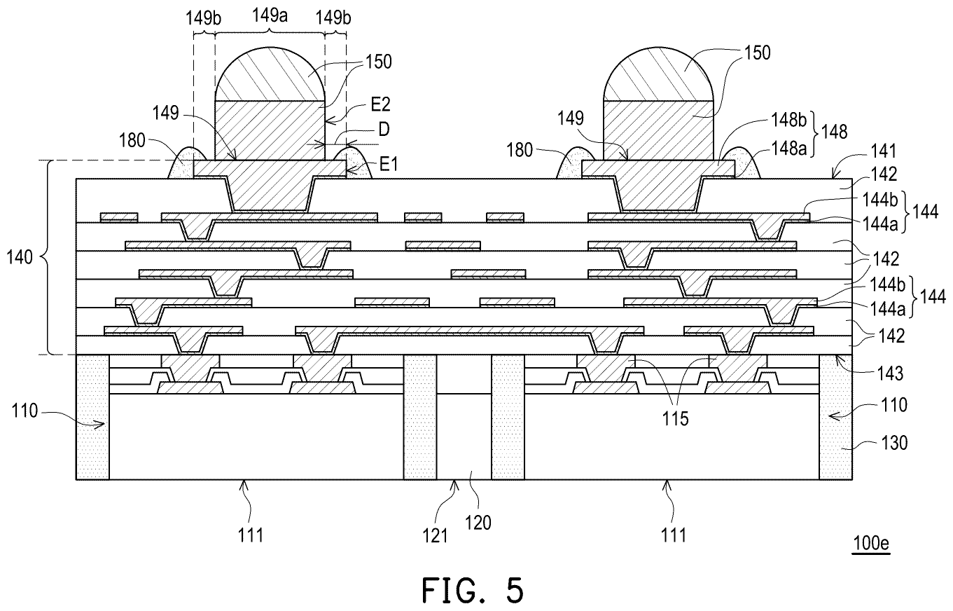

FIG. 5 is a schematic cross-sectional view illustrating an integrated fan-out package in accordance with some alternative embodiments of the disclosure. Referring to FIG. 5, the integrated fan-out package 100e in FIG. 5 is similar to the integrated fan-out package 100a in FIG. 1F, so similar elements are denoted by the same reference numeral and the detailed description thereof is omitted herein. The difference between the integrated fan-out package 100e in FIG. 5 and the integrated fan-out package 100a in FIG. 1F lies in that in the integrated fan-out package 100be further includes an underfill material 180 is disposed on a portion of the second area 149b of the configuration surface 149. In some embodiments, the underfill material 180 covers a portion of the second area 149b of the configuration surface 149. In some embodiments, the underfill material 180 covers a portion of the second area 149b of the configuration surface 149 and extends alone the first edge E1 of the second area 149b to cover the first surface 141 of the redistribution structure 140.

In accordance with some embodiments of the disclosure, an integrated fan-out package includes a redistribution structure, a die, an encapsulant and a conductive bump. The redistribution structure has a first surface and a second surface opposite to the first surface, wherein the redistribution structure comprises an under-bump metallization (UBM) pattern disposed on the first surface. The die is disposed on the second surface of the redistribution structure. The encapsulant encapsulates the die. The conductive bump is disposed on the UBM pattern, wherein the UBM pattern has a configuration surface over the first surface, the conductive bump is located on the configuration surface, and a bottom area of the conductive bump is smaller than an area of configuration surface.

In accordance with some embodiments of the disclosure, an integrated fan-out package includes a redistribution structure, a die, an encapsulant, a conductive bump and an underfill material. The redistribution structure has a first surface and a second surface opposite to the first surface, wherein the redistribution structure comprises an under-bump metallization (UBM) pattern disposed on the first surface. The die is disposed on the second surface of the redistribution structure. The encapsulant encapsulates the die. The conductive bump is disposed on the UBM pattern, wherein the UBM pattern has a configuration surface over the first surface, the configuration surface has a first area and a second area surrounding the first area, the conductive bump is located in the first area. The underfill material is disposed on a portion of the second area of the configuration surface.

In accordance with some embodiments of the disclosure, a manufacturing method of an integrated fan-out package includes placing a die on a substrate; encapsulating the die by an encapsulant; forming a redistribution structure on the encapsulant, wherein the redistribution structure has a first surface and a second surface opposite to the first surface and comprises an under-bump metallization (UBM) pattern disposed on the first surface, the die is disposed on the second surface; and forming a conductive bump on the UBM pattern, wherein the UBM pattern has a configuration surface over the first surface, the conductive bump is located on the configuration surface, and a bottom area of the conductive bump is smaller than an area of configuration surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated fan-out package, comprising:
a redistribution structure having a first surface and a second surface opposite to the first surface, wherein the redistribution structure comprises an under-bump metallization (UBM) pattern disposed on the first surface;
a die disposed on the second surface of the redistribution structure;
an encapsulant encapsulating the die; and
a conductive bump disposed on the UBM pattern, wherein the UBM pattern has a configuration surface over the first surface, the conductive bump is located on the configuration surface, and a bottom area of the conductive bump is smaller than an area of configuration surface.

2. The integrated fan-out package of claim 1, wherein the conductive bump comprises a copper pillar.

3. The integrated fan-out package of claim 1, wherein the UBM pattern comprises a portion and a second portion, the first portion has the configuration surface, the second portion is disposed on the configuration surface and surrounds the conductive bump.

4. The integrated fan-out package of claim 3, wherein a first extending direction of the first portion is different from a second extending direction of the second portion.

5. The integrated fan-out package of claim 3, wherein a first height of the second portion is smaller than a second height of the conductive bump.

6. The integrated fan-out package of claim 1, further comprising:
an integrated passive device (IPD) disposed on the first surface of the redistribution structure.

7. The integrated fan-out package of claim 6, wherein a first height of the IPD is smaller than a second height of the conductive bump.

8. The integrated fan-out package of claim 6, further comprising:
an underfill disposed between the IPD and the redistribution structure.

9. The integrated fan-out package of claim 1, further comprising:
a dummy die disposed on the second surface of the redistribution structure, wherein the encapsulant further encapsulates the dummy die.

10. The integrated fan-out package of claim 9, wherein the dummy die is electrically floating.

11. The integrated fan-out package of claim 9, wherein the encapsulant exposes a first rear surface of the die and a second rear surface of the dummy die.

12. An integrated fan-out package, comprising:
a redistribution structure having a first surface and a second surface opposite to the first surface, wherein the redistribution structure comprises an under-bump metallization (UBM) pattern disposed on the first surface;
a die disposed on the second surface of the redistribution structure;
an encapsulant encapsulating the die;
a conductive bump disposed on the UBM pattern, wherein the UBM pattern has a configuration surface over the first surface, the configuration surface has a first area and a second area surrounding the first area, the conductive bump is located in the first area; and
an underfill material disposed on a portion of the second area of the configuration surface.

13. The integrated fan-out package of claim 12, wherein the conductive bump comprises a copper pillar.

14. The integrated fan-out package of claim 12, wherein the UBM pattern comprises a portion and a second portion, the first portion has the configuration surface, the second portion is disposed on the configuration surface and surrounds the conductive bump.

15. The integrated fan-out package of claim 12, further comprising:
an integrated passive device (IPD) disposed on the first surface of the redistribution structure.

16. The integrated fan-out package of claim 12, further comprising:
a dummy die disposed on the second surface of the redistribution structure, wherein the encapsulant further encapsulates the dummy die.

17. A manufacturing method of an integrated fan-out package, comprising:
placing a die on a carrier;
encapsulating the die by an encapsulant;
forming a redistribution structure on the encapsulant, wherein the redistribution structure has a first surface and a second surface opposite to the first surface and comprises an under-bump metallization (UBM) pattern disposed on the first surface, the die is disposed on the second surface; and
forming a conductive bump on the UBM pattern, wherein the UBM pattern has a configuration surface over the first surface, the conductive bump is located on the configuration surface, and a bottom area of the conductive bump is smaller than an area of configuration surface.

18. The manufacturing method of the integrated fan-out package of claim 17, further comprising:
placing an integrated passive device (IPD) on the first surface of the redistribution structure.

19. The manufacturing method of the integrated fan-out package of claim 17, further comprising:
placing a dummy die on the carrier before encapsulating the die by the encapsulant.

20. The manufacturing method of the integrated fan-out package of claim 17, further comprising:
removing the carrier after forming the conductive bump on the UBM pattern to expose a rear surface of the die.
